(19) United States
(12) Patent Application Publication
(10) Pub. No.: US 2025/0207248 A1
(43) Pub. Date: Jun. 26, 2025

(54) NANOCRYSTALLINE DIAMOND AND ULTRA-NANOCRYSTALLINE DIAMOND FILMS BY CATALYTIC CVD

(71) Applicant: Applied Materials, Inc., Santa Clara, CA (US)

(72) Inventors: David Masayuki ISHIKAWA, Mountain View, CA (US); Abhijit Basu MALLICK, Fremont, CA (US); Bharatwaj RAMAKRISHNAN, Sunnyvale, CA (US); Visweswaren SIVARAMAKRISHNAN, Cupertino, CA (US); Karthik JANAKIRAMAN, San Jose, CA (US)

(21) Appl. No.: 18/958,006

(22) Filed: Nov. 25, 2024

Related U.S. Application Data
(60) Provisional application No. 63/612,745, filed on Dec. 20, 2023.

(51) Int. Cl. C23C 16/27; C23C 16/455

(52) U.S. Cl. CPC C23C 16/271; C23C 16/45587

(57) ABSTRACT

A hot wire chemical vapor deposition (HWCVD) source, for example, a filament, and methods for deposition of diamond-like carbon hard mask films are provided. The HWCVD source includes carbide filaments or boride filaments. The boride filaments and carbide filaments described herein can be solid filaments. Examples of the carbide and boride filaments described can include or be silicon carbide filaments, tantalum carbide filaments, hafnium carbide filaments, and lanthanum hexaboride filaments.

### CROSS-REFERENCE TO RELATED APPLICATIONS

This application claims the benefit of U.S. Provisional Patent Application Ser. No. 63/612,745, filed Dec. 20, 2023, which is incorporated by reference herein in its entirety.

### TECHNICAL FIELD

Implementations of the present disclosure generally relate to systems and methods of forming inert carbon films. More particularly, implementations generally relate to deposition of diamond-like carbon films using a catalytic chemical vapor deposition (CVD) process.

### BACKGROUND

As the semiconductor industry introduces new generations of integrated circuits (IC's) having higher performance and greater functionality, the density of the elements that form those IC's is increased, while the dimensions, size and spacing between the individual components or elements are reduced. While in the past such reductions were limited only by the ability to define the structures using photolithography, device geometries having dimensions measured in micrometers or nanometers have created new limiting factors, such as the conductivity of the metallic elements, the dielectric constant of the insulating material(s) used between the elements or challenges in 3D NAND or DRAM processes. These limitations may be benefitted by more durable and higher hardness hardmasks.

Current carbon hardmask compositions are expected to be insufficient as DRAM and NAND continue their scaling down to under approximately 10-nm regime. This downscaling will involve even higher aspect ratio deep contact hole or trench etch. The high aspect ratio etch issues include clogging, hole-shape distortion, and pattern deformation, top critical dimension blow up, line bending, profile bowing are generally observed in these applications. Many etch challenges are dependent on the hardmask material property. Deep contact hole deformation is due to lower density of the hardmask and poor thermal conductivity. Slit pattern deformation or line bending is due to hardmask material lower selectivity and stress.

Therefore, there is a need for an etch hardmask with higher density, higher etch selectivity, lower stress and excellent thermal conductivity.

### SUMMARY

Implementations of the present disclosure generally relate to systems and methods of forming inert carbon films. More particularly, implementations generally relate to deposition of diamond-like carbon films using a catalytic chemical vapor deposition (CVD) process.

In one aspect, a method of forming a nanocrystalline diamond layer is provide. The method includes positioning a substrate in a processing region of a processing chamber having a filament disposed therein. The method further includes flowing current through the filament to raise a temperature of the filament to a first temperature. The method further includes flowing a carbon containing deposition gas over the filament. The method further includes depositing the nanocrystalline diamond layer over the substrate using species decomposed from the carbon containing deposition gas.

Implementations may include one or more of the following. The filament is selected from a carbide containing filament or a boride containing filament. The carbide containing filament or the boride containing filament is selected from a silicon carbide (SiC) filament, a tantalum carbide (TaC) filament, a lanthanum hexaboride filament, or a hafnium carbide filament. The first temperature is in a range from about 1500 degrees Celsius and about 2500 degrees Celsius. The processing region is maintained a pressure of 1 mTorr or greater. The processing chamber further includes a gas distribution plate, the gas distribution plate including a ceramic body, the ceramic body having a first surface, a second surface opposite the first surface, a side surface extending from the first surface to the second surface, a plurality of holes extending from the first surface to the second surface, and a plurality of radial cavities formed in the second surface, wherein each of the radial cavities is aligned with a corresponding plurality of holes, and the filament positioned in the radial cavities. Flowing the carbon containing deposition gas over the filament comprises flowing the carbon containing deposition gas through the plurality of holes and over the filament positioned within the corresponding radial cavity.

In another aspect, a hot wire chemical vapor deposition (HWCVD) apparatus is provided. The HWCVD apparatus includes a chamber body defining an internal processing volume, a substrate support having a support surface for supporting a substrate, a gas distribution plate positioned opposite the substrate support. The gas distribution plate includes a ceramic body. The ceramic body includes a first surface, a second surface opposite the first surface, a side surface extending from the first surface to the second surface, a plurality of holes extending from the first surface to the second surface, and a plurality of radial cavities formed in the second surface. The HWCVD apparatus further includes a filament positioned in the radial cavities, wherein the filament is selected from a carbide containing filament or a boride containing filament.

Implementations may include one or more of the following. The carbide containing filament or the boride containing filament is selected from a silicon carbide (SiC) filament, a tantalum carbide (TaC) filament, a lanthanum hexaboride filament, or a hafnium carbide filament. The apparatus further includes a power source for selectively passing a current through the filament to resistively heat material of the filament. Each radial cavity extends from a center portion of the ceramic body toward the side surface of the ceramic body. Each of the radial cavities is aligned with a corresponding plurality of holes such that after process gas exits the plurality of holes the process gas flows over the filament positioned within the corresponding radial cavity. The filament includes a cylindrical body having a central portion having a first end and a second end, a first end portion extending from the first end of the central portion, and a second end portion extending from the second end of the central portion, wherein the central portion has a first diameter and at least one of the first end portion and the second end portion has a second diameter, and the second diameter is greater than the first diameter. The HWCVD apparatus further includes a controller configured to execute instructions stored on a computer readable medium for a method of forming a nanocrystalline diamond layer, the method including flowing current through the filament to raise a temperature of the filament to a first temperature, flowing a carbon containing deposition gas over the filament, and depositing a nanocrystalline diamond layer over the substrate using species decomposed from the carbon containing deposition gas.

In yet another aspect, a gas distribution plate is provided. The gas distribution plate includes a ceramic body. The ceramic body includes a first surface, a second surface opposite the first surface, a side surface extending from the first surface to the second surface, a plurality of holes extending from the first surface to the second surface, and a plurality of radial cavities formed in the second surface, and a filament positioned in the radial cavities, wherein the filament is selected from a carbide containing filament or a boride containing filament.

Implementations may include one or more of the following. The carbide containing filament or the boride containing filament is selected from a silicon carbide (SiC) filament, a tantalum carbide (TaC) filament, a lanthanum hexaboride filament, or a hafnium carbide filament. Each radial cavity extends from a center portion of the ceramic body toward the side surface of the ceramic body. Each of the radial cavities is aligned with a corresponding plurality of holes such that after process gas exits the plurality of holes the process gas flows over the filament positioned within the corresponding radial cavity. The filament includes a cylindrical body. The cylindrical body includes a central portion having a first end and a second end, a first end portion extending from the first end of the central portion, and a second end portion extending from the second end of the central portion, wherein the central portion has a first diameter and at least one of the first end portion and the second end portion has a second diameter, and the second diameter is greater than the first diameter. The ceramic body includes graphite and the ceramic body has a carbide coating disposed thereon.

In another aspect, a non-transitory computer readable medium has stored thereon instructions, which, when executed by a processor, causes the process to perform operations of the above apparatus and/or method.

### BRIEF DESCRIPTION OF THE DRAWINGS

So that the manner in which the above-recited features of the present disclosure can be understood in detail, a more particular description of the aspects, briefly summarized above, may be had by reference to implementations, some of which are illustrated in the appended drawings. It is to be noted, however, that the appended drawings illustrate only typical implementations of this disclosure and are therefore not to be considered limiting of its scope, for the disclosure may admit to other equally effective implementations.

FIG. 1 illustrates a side view of a device having a nanocrystalline diamond layer formed thereon in accordance with one or more implementations of the present disclosure.

FIG. 2 illustrates an exemplary flow chart for forming a nanocrystalline diamond layer via a hot wire chemical vapor deposition (HWCVD) process in accordance with one or more implementations of the present disclosure.

FIG. 3 illustrates an exemplary flow chart for processing a substrate including a nanocrystalline diamond layer in accordance with one or more implementations of the present disclosure.

FIG. 4 illustrates a schematic side view of a HWCVD processing chamber in accordance with one or more implementations of the present disclosure.

FIG. 5A illustrates a cross-sectional view of a gas distribution plate in accordance with one or more implementations of the present disclosure.

FIG. 5B illustrates a perspective cutaway view of the gas distribution plate of FIG. 5A in accordance with one or more implementations of the present disclosure.

FIG. 5C illustrates another perspective cutaway view of the gas distribution plate of FIG. 5A in accordance with one or more implementations of the present disclosure.

FIG. 6A illustrates a cross-sectional side view of a filament formed in accordance with one or more implementations of the present disclosure.

FIG. 6B illustrates a cross-sectional view of the filament of FIG. 6A taken along line 6B-6B in accordance with one or more implementations of the present disclosure.

To facilitate understanding, identical reference numerals have been used, where possible, to designate identical elements that are common to the figures. It is contemplated that elements and features of one implementation may be beneficially incorporated in other implementations without further recitation.

### DETAILED DESCRIPTION

Implementations of the present disclosure generally relate to systems and methods of forming inert carbon films. More particularly, implementations generally relate to deposition of diamond-like carbon films using a catalytic or hot wire chemical vapor deposition (HWCVD) process. The HWCVD processing techniques described herein may advantageously eliminate or reduce the metal contamination which is present in films deposited by currently available metallic filaments and HWCVD processes. Implementations of the present disclosure may thus provide one or more of the following benefits: improved film quality as compared to use of tungsten filaments, extended filament lifetime, greater equipment uptime, higher yield, and higher throughput.

Diamond is known as a high hardness material. Due to high hardness, surface inertness, and low friction coefficient, synthetic diamond has been applied as a protective coating and in microelectromechanical systems (MEMS) among other uses. Diamond-like carbon films, such as nanocrystalline diamond (NCD) and ultra-nanocrystalline diamond (UNCD), have been synthesized by hot filament or catalytic CVD and microwave CVD. However, there are a variety of difficulties with both hot filament CVD and microwave CVD of nanocrystalline diamond films.

In hot filament CVD, a metal filament is used to activate precursor gases for deposition. The metal filament is exposed to the precursor gases during the film forming process. As a result, precursor gases can react with the metal filament leading to metal contamination issues in the deposited film. Compared to hot filament CVD, microwave CVD has fewer contamination issues. However microwave CVD involves a high process pressure which can affect film uniformity. Moreover, although microwave plasma from microwave CVD has relatively low energy ions, these ions still can attack the diamond-like carbon film grain boundary and induce grain structure disorder.

Implementations of the present disclosure include a HWCVD source, for example, a filament, and methods for NCD and UNCD hard mask deposition. The HWCVD source includes multi-composition filaments such as carbide filaments or boride filaments. The boride filaments and carbide filaments described herein can be solid filaments. Examples of the carbide and boride filaments described can include or be silicon carbide filaments, tantalum carbide filaments, hafnium carbide filaments, and lanthanum hexaboride filaments. In one or more implementations, the carbide and boride filaments described are composed of a material selected from the group comprising, consisting of, or consisting essentially of silicon carbide, tantalum carbide, hafnium carbide, or lanthanum hexaboride. In one or more implementations, the carbide and boride filaments have no or substantially no free metal in the filament, which prevents or reduces metal contamination in the deposited film. During the HWCVD process, the filaments activate hydrocarbon precursors, for example, methane (CH₄), acetone (CH₃COCH₃), acetylene (C₂H₂) or other carbon precursors in a hydrogen (H₂) carrier gas.

Implementations of the present disclosure further include a refractory ceramic gas diffuser design. The refractory ceramic gas diffuser may be a carbide-coated graphite gas diffuser designed to accommodate the carbide and boride filaments described. The refractory ceramic gas diffuser facilitates assembly, extends filament life, and may be optimized to tune uniformity. The inventive carbide and boride filaments are more durable than traditional carbide-coated graphite alternatives. The refractory ceramic diffuser facilitates serviceability, provides a metal-free process kit and elevated temperature environment to improve filament reliability.

In one or more implementations, which can be combined with other implementations, a filament for use in a HWCVD process is provided. The filament can be a carbide filament or a boride filament. The filament can be free from metal. The filament can be a free-standing linear filament. The filament can be a helical filament. The helical filament design has a high surface area and thermal expansion accommodating geometry. The filament can have a uniform diameter extending along a length of the filament. The filament can have a non-uniform diameter, for example, the end portions of the filament can have a larger diameter than a central portion of the filament. This larger diameter can facilitate positioning of the carbide or boride filaments within the refractory ceramic diffuser described.

In one or more implementations, which can be combined with other implementations, the carbide or boride filament described is formed by a laser-assisted chemical vapor deposition (LCVD) process. During the LCVD process, pure precursor gases (such as silane and ethylene in the case of SiC fiber production) are introduced into a reactor within which a suitable substrate such as glassy carbon is positioned, and laser light is focused onto the substrate. The heat generated by the focused laser beam breaks down the precursor gases locally, and the atomic species deposit onto the substrate surface and build up locally to form a fiber. If either the laser or the substrate is pulled away from this growth zone at the growth rate a continuous fiber filament will be produced with the very high purity of the starting gases. With this technique there are virtually no unwanted impurities, and in particular no performance-robbing oxygen.

The filament can be or include a solid silicon carbide (SiC) filament, a solid tantalum carbide (TaC) filament, a solid lanthanum hexaboride filament, or a solid hafnium carbide filament.

In one example where the filament is a solid silicon carbide filament, the solid silicon carbide filament is formed via a LCVD process which includes flowing a silicon-containing precursor, for example, silane (SiH4), and a carbon-containing precursor, for example, ethylene (C2H4) or methane (CH4), at a pressure in a range from about two bar to about six bar to produce a solid silicon carbide filament. The solid silicon carbide filament can have a diameter in a range from about 13 to about 120 micrometers.

In another example where the filament is a solid tantalum carbide filament, the solid tantalum carbide filament is formed via a LCVD process which includes flowing a tantalum-containing precursor, for example, tantalum pentachloride (TaCl5), and a carbon-containing precursor, for example, methane (CH4) at a pressure in a range from about 50 mbar to about 100 mbar to produce a solid tantalum carbide filament. The solid tantalum carbide filament can have a diameter in a range from about 50 to about 80 micrometers.

In yet another example where the filament is a solid lanthanum hexaboride filament, the solid lanthanum hexaboride filament is formed via a LCVD process which includes nido-pentaborane (B5H9) and nido-decaborane (B10H14) co-pyrolysis with lanthanum (III) chloride. The solid lanthanum hexaboride filament can have a diameter in a range from about 50 to about 80 micrometers.

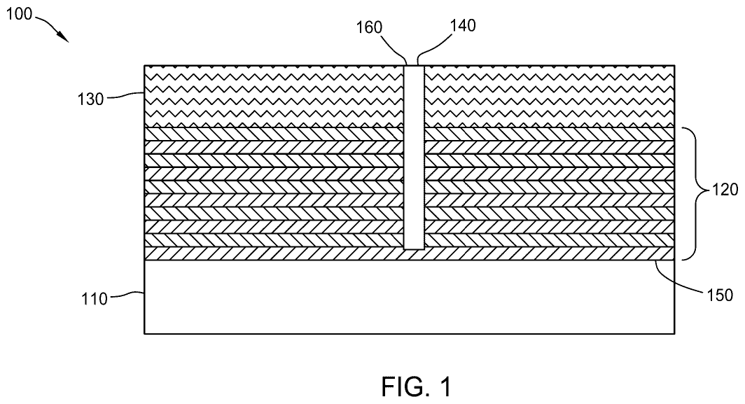

FIG. 1 illustrates a side view of a device 100 having a nanocrystalline diamond layer 130 formed thereon in accordance with one or more implementations of the present disclosure. The device 100 is a NAND device. The device 100 includes a substrate 110, a plurality of device layers 120 formed on the substrate 110, and the nanocrystalline diamond layer 130 formed thereon. The nanocrystalline diamond layer 130 is a nanocrystalline diamond (NCD) film or an ultra-nanocrystalline diamond (UNCD) film formed according to the HWCVD methods described herein.

The substrate 110 can be any suitable semiconducting substrate, for example, monocrystalline silicon, IV-IV compounds such as silicon-germanium or silicon-germanium-carbon, III-V compounds, II-VI compounds, epitaxial layers over such substrates, or any other semiconducting or non-semiconducting material, such as silicon oxide, glass, plastic, metal or ceramic substrate. The substrate 110 may include integrated circuits fabricated thereon, such as driver circuits for a memory device (not shown).

The plurality of device layers 120 can be formed over the surface of the substrate 110. The plurality of device layers 120 can be deposited layers which form components of a 3D vertical NAND structure. Components which are formed by all or part of the plurality of device layers (e.g., dielectrics, or discrete charge storage segments). The dielectric portions may be independently selected from any one or more same or different electrically insulating materials, such as silicon oxide, silicon nitride, silicon oxynitride, or other high-k insulating materials. In one or more implementations, which can be combined with other implementations, the device layers 120 include silicon oxide/silicon nitride pairs deposited in an alternating fashion. The pairs can be between 100 and 600 Å in total width. The number of pairs can be greater than 10 pairs, such as 32 pairs, 64 pairs or greater. In one implementation, the number of pairs are between 10 and 64 pairs. The total thickness can be in a range from about 2 and about 4 microns.

The discrete charge storage segments may include a conductive (e.g., metal or metal alloy such as titanium, platinum, ruthenium, titanium nitride, hafnium nitride, tantalum nitride, zirconium nitride, or a metal silicide such as titanium silicide, nickel silicide, cobalt silicide, or a combination thereof) or semiconductor (e.g., polysilicon) floating gate, conductive nanoparticles, or a discrete charge storage dielectric (e.g., silicon nitride or another dielectric) feature. However, it should be understood that a dielectric charge storage feature or other floating gate material may be used instead.

The nanocrystalline diamond layer 130, for example, the NCD or UNCD layer, is a crystalline carbon layer with a high sp3 content and a small crystal size. The most common chemical bonds in amorphous and nanocrystalline carbon are threefold (sp2 bonding) and fourfold (sp3) bonding coordination. In the sp3 configuration, a carbon atom forms four sp3 orbitals making a strong sigma bond to the adjacent atom. In carbon films with high sp3 content, the sp3 content is greater than 80%, such as greater than about 90% or greater than about 95% or greater than about 99%. The nanocrystalline diamond layer 130 shown here has a high sp3 content (e.g., nanocrystalline diamond grains) is supported by a sp2 matrix (e.g., graphite). In one or more implementations where the nanocrystalline diamond layer 130 is a UNCD film the small crystal size is a crystal size of less than 6 nm, such as between 2 nm and 5 nm. In one or more implementations where the nanocrystalline diamond layer 130 is a NCD film, the small crystal size is a crystal size of less than 100, such as between 5 nm and 100 nm. The nanocrystalline diamond layer 130 can have a surface roughness with a root mean square of height deviation of less than 6 nm. The nanocrystalline diamond layer 130 can have a density of between 2.5 g/cm³ and 3.5 g/cm³, such as a density of 3 g/cm³. The nanocrystalline diamond layer 130 can have a stress of between −50 MPa and −150 MPa, such as a stress of between −80 MPa and −120 MPa. The nanocrystalline diamond layer 130 can have a blanket etch selectivity of between 2 and 4 as compared to currently available diamond-like carbon films.

In one example where the nanocrystalline diamond layer 130 is a UNCD film, the UNCD film has an sp3 content of greater than about 95% or greater than about 98%; a density in a range from about 3,000 to about 3500 kg/m3 such as about 3300 kg/m3; a surface roughness less than about 10 nm, for example, in a range from about 5 nm to about 7 nm; a gran size less than 6 nm, for example in a range from about 2 nm to about 5 nm; a film stress in a range from about 50 MPa to about 200 MPa, such as a stress in a range from about 100 MPa to about 200 MPa.

In one example where the nanocrystalline diamond layer 130 is a NCD film, the NCD film has an sp3 content of greater than about 98% or greater than about 99%; a density in a range from about 3,300 to about 3600 kg/m3 such as about 3500 kg/m3; a surface roughness less than about 30 nm, for example, in a range from about 5 nm to about 25 nm; a gran size less than 100 nm, for example in a range from about 5 nm to about 100 nm; a film stress in a range from about −200 MPa to about 400 MPa, such as a stress in a range from about −100 MPa to about 300 MPa.

The device 100 includes a channel 140. The channel 140 shown here is formed through the nanocrystalline diamond layer 130 and the plurality of device layers 120. The channel 140 can be substantially perpendicular to a first surface 150 of the substrate 110. For example, the channel 140 may have a pillar shape. The channel 140 can extend substantially perpendicularly to the first surface 150 of the substrate 110. An optional body contact electrode (not shown) may be disposed in the substrate 110 to provide body contact to a connecting portion of the channel 140 from below. In some implementations, the channel 140 is a filled feature. In some other implementations, the channel 140 is hollow. In these implementations, an insulating fill material 160 may be formed to fill the hollow part surrounded by the channel 140. The insulating fill material 160 may include any electrically insulating material, such as silicon oxide, silicon nitride, silicon oxynitride, or other high-k insulating materials.

Any suitable semiconductor materials can be used for the channel 140, for example silicon, germanium, silicon germanium, or other compound semiconductor materials, such as III-V, II-VI, or conductive or semiconductive oxides, or other materials. The semiconductor material may be amorphous, polycrystalline or single crystal. The semiconductor channel material may be formed by any suitable deposition method. For example, in one implementation, the semiconductor channel material is deposited by low pressure chemical vapor deposition (LPCVD). In some other implementations, the semiconductor channel material may be a recrystallized polycrystalline semiconductor material formed by recrystallizing an initially deposited amorphous semiconductor material.

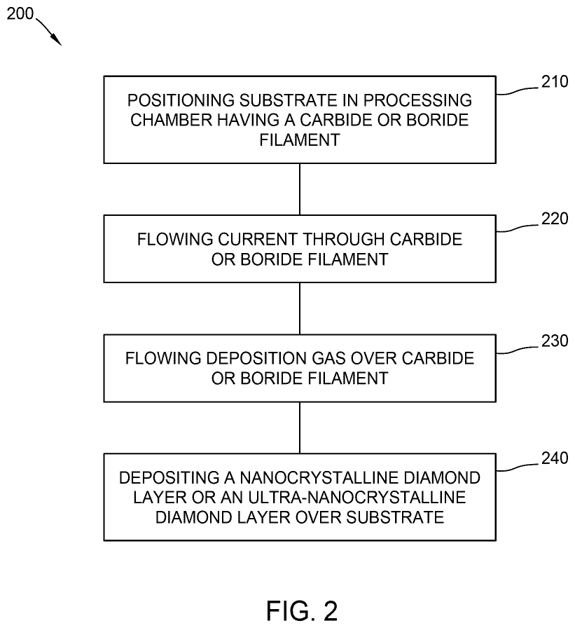

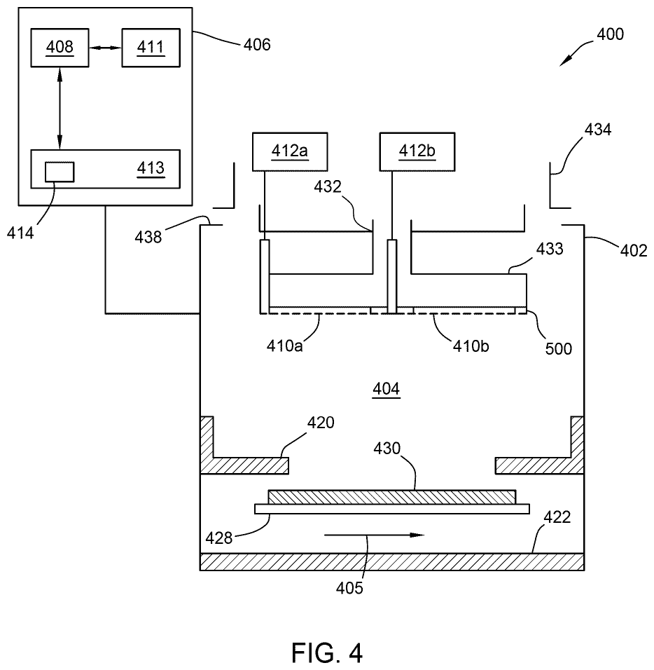

FIG. 2 illustrates an exemplary flow chart of a method 200 for forming a nanocrystalline diamond layer via a hot wire chemical vapor deposition (HWCVD) process in accordance with one or more implementations of the present disclosure. The method 200 generally begins at operation 210 where a substrate is positioned in a processing chamber. The processing chamber may be a HWCVD processing chamber, for example the processing chamber 400 depicted in FIG. 4. The processing chamber has a filament or a plurality of filaments disposed in the processing chamber. The filament or plurality filaments may be selected from carbide filaments or boride filaments as described herein. The substrate may be the substrate 110 having a device layer formed thereon, for example, the device layer 120.

At operation 220, current may be flowed through the filaments to raise the temperature of the filaments to a processing temperature. Current may be provided to the filaments from a power source. The amount of current provided may be selected to raise the temperature of the filaments to a processing temperature. The processing temperature can be in a range from about 1500 to about 2500 degrees Celsius (although other temperatures may be used) at pressures of, for example, about 1 mTorr or greater, or about 10 mTorr or greater (e.g., typical HWCVD operating conditions for certain applications such as the deposition of diamond-like carbon films).

At operation 230, a deposition gas is provided to the HWCVD tool. The deposition gas may comprise any suitable process gas to be used in the deposition process. In some implementations, the deposition gas may include a gas that can thermally decompose when exposed to be heated filaments such that species from the decomposed process gas may be deposited on an underlying substrate. The deposition gas includes a carbon-containing precursor and optionally a hydrogen-containing gas. The carbon-containing gas may be a hydrocarbon. In one or more implementations, the hydrocarbon has a general formula CₙH₂ₙ₊₂ where n is in a range from 1 to 120. In particular implementations, the hydrocarbon is selected from one or more of methane (CH₄), ethane (C₂H₆), propane (C₃H₈), butane (C₄H₁₀), pentane (C₅H₁₂), hexane (C₆H₁₄), heptane (C₇H₁₆), ethene (C₂H₄), propene (C₃H₆), butene (C₄H₈), pentene (C₅H₁₀), hexene (C₆H₁₂), heptane (C₇H₁₄), ethyne (C₂H₂), propyne (C₃H₄), butyne (C₄H₆), pentyne (C₅H₈), hexyne (C₆H₁₀), and heptyne (C₇H₁₂). The hydrogen-containing gas can include H₂, H₂O, NH₃ or other hydrogen-containing molecules. The deposition gas can further include an inert gas, for example, argon or helium.

At operation 240, a material may be deposited on the substrate using species decomposed from the process gas. The material may be a nanocrystalline diamond layer or an ultra-nanocrystalline diamond layer formed over a substrate. For example, the nanocrystalline diamond layer 130 formed on the device layer 120. As discussed above, the material deposited on the substrate generally comprises species from the deposition gas. Upon completion of the deposition of material at 240 the method 200 generally ends and the substrate may be further processed.

In some implementations, the method 200 may be repeated to deposit materials on the same substrate or on a second substrate provided to the HWCVD tool. For example, in some implementations, after the materials deposited on the substrate at operation 240, the substrate in the chamber may be replaced with a second substrate while maintaining the filament at the processing temperature. A second deposition gas may be provided to the processing chamber after the second substrate is provided. The second deposition gas may be the same as the first deposition gas (for example, when the same materials to be deposited) or the second deposition gas may be different than the first deposition gas (for example, when different materials are to be deposited on the second substrate). A material may then be deposited on the second substrate using species decomposed from the second deposition gas.

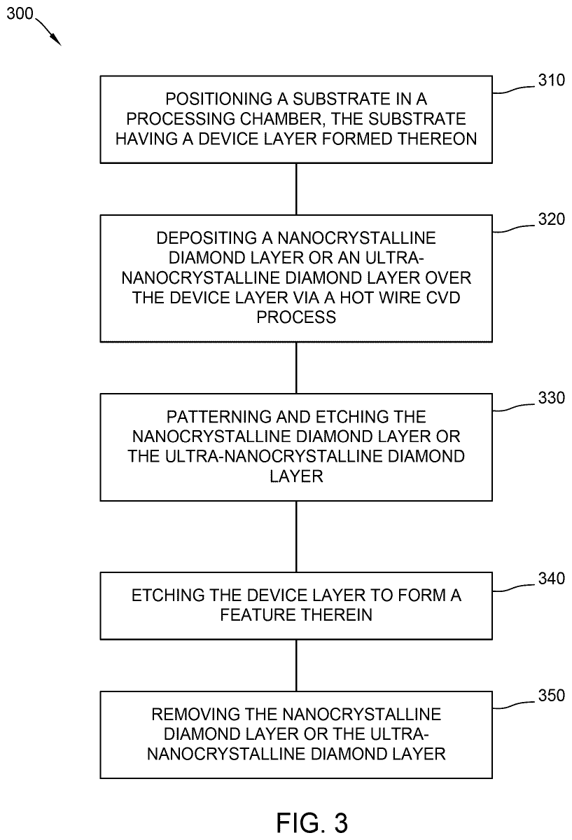

FIG. 3 illustrates an exemplary flow chart of a method 300 for processing a substrate including a nanocrystalline diamond layer in accordance with one or more implementations of the present disclosure. The etching chemistry for the device layers is substantially inert with regard to nanocrystalline diamond. As such, implementations described herein use a hard mask comprising a nanocrystalline diamond layer formed as described herein, rather than a traditional hardmask. The nanocrystalline diamond layer allows for high aspect ratio features to be formed while avoiding the bowing and the bending of non-circular etching of the feature as well as avoiding pattern collapse as described above, with reference to traditional hardmasks. The nanocrystalline diamond layer achieves these benefits by having both a high physical resistivity, being chemically inert and having a high thermal conductivity. Having a high physical resistivity and being chemically inert allow for improved etch selectivity over previously known hardmasks. Improved etch selectivity allows for a good etch profile to be maintained. Further, the nanocrystalline diamond layer is much closer to diamond than standard carbon hardmasks, which gives the layer a high thermal conductivity. During an etch process, a significant amount of heat is accumulated. This heat, if it remains trapped in underlying layers, can create warping. The nanocrystalline diamond layer allows for efficient heat transfer, which prevents warping or other heat-related distortion. The nanocrystalline diamond layer can then be easily and selectively removed by ashing in the presence of an oxygen-containing gas or a nitrogen-containing gas.

The method 300 begins at operation 310 by positioning a substrate in a processing chamber, the substrate having a processing surface and a supporting surface. The substrate can be of any composition, such as a crystalline silicon substrate. The substrate can also include one or more features, such as a via or an interconnect. The substrate can be supported on a substrate support. The substrate support can be maintained in a specific temperature range. In one implementation, the substrate support is maintained in a temperature range of between about 500 degrees Celsius and about 650 degrees Celsius. The processing chamber may be a HWCVD processing chamber, for example the processing chamber 400 depicted in FIG. 4. The processing chamber has a filament or a plurality of filaments disposed in the processing chamber. The filament or plurality filaments may be selected from carbide filaments or boride filaments as described herein. The substrate may be the substrate 110 having a device layer formed thereon, for example, the device layer 120.

At operation 320, a nanocrystalline layer or an ultra-nanocrystalline diamond layer is formed over the device layer via a hot wire CVD process. Operation 320 may be performed according to the method 200.

At operation 330, the nanocrystalline diamond layer or the ultra-nanocrystalline diamond layer can then be patterned and etched. Patterning can include deposition of a photoresist over the nanocrystalline layer or the ultra-nanocrystalline diamond layer. The photoresist is then exposed to an appropriate wavelength of radiation to create a pattern. The pattern is then etched into both the photoresist and then the nanocrystalline diamond layer or the ultra-nanocrystalline diamond layer.

At operation 340, the device layer can then be etched to form a feature, for example, the channel 140. With the pattern formed in the nanocrystalline diamond layer or the ultra-nanocrystalline diamond layer, the device layer can then be etched. The device layer is etched by an etchant which is selective for the device layer over the nanocrystalline diamond layer or the ultra-nanocrystalline diamond layer. The device layer is etched using chemistry and techniques well known in the art. In one or more implementations, the etchant is a chlorine containing etchant.

At operation 350, the nanocrystalline diamond layer or the ultra-nanocrystalline diamond layer can then be removed from the surface of the device layer. The nanocrystalline diamond layer or the ultra-nanocrystalline diamond layer can be ashed, for example, from the surface of the device layer using a plasma ash process. The plasma ash process can include activating an oxygen-containing gas, such as O₂.

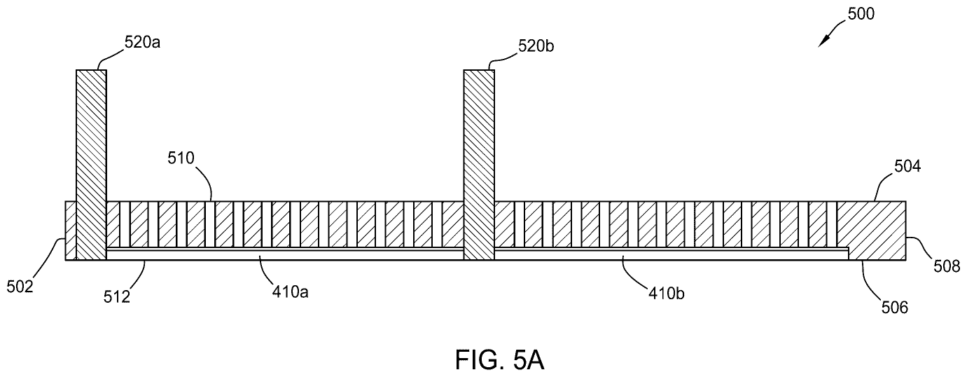

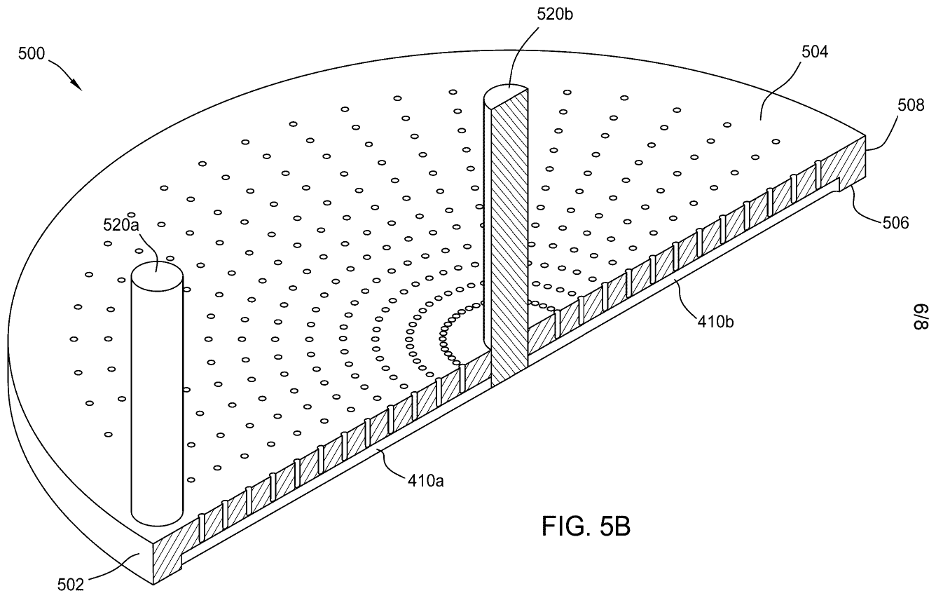

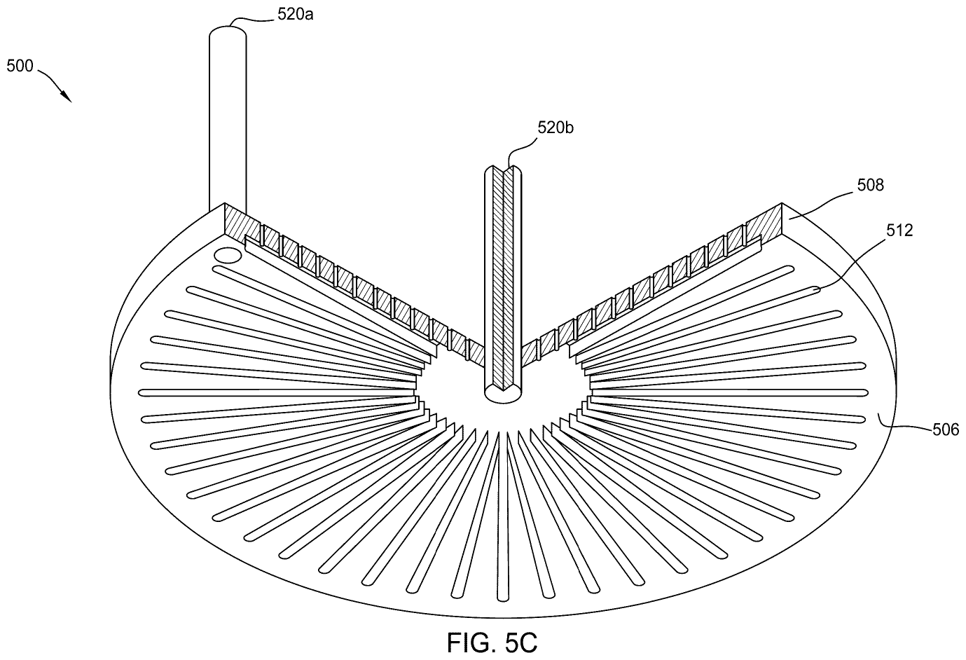

FIG. 4 illustrates a schematic side view of a HWCVD processing chamber 400 in accordance with one or more implementations of the present disclosure. The HWCVD processing chamber 400 generally includes a chamber body 402 having an internal processing volume 404. The processing chamber 400 includes a showerhead assembly 433 disposed within the internal processing volume 404. The showerhead assembly 433 includes a gas distribution plate 500 incorporating a plurality of filaments 410a-b, or wires. The gas distribution plate 500 will be described in additional detail in FIGS. 5A-5C. Although depicted as positioned in the gas distribution plate 500, the filaments 410a-b may be positioned in other portions of the internal processing volume 404. For example, the plurality of filaments 410 may also be a single wire routed back and forth across the internal processing volume 404. The plurality of filaments 410 comprise a HWCVD source. The filaments 410 are made of carbides or borides as described herein. Each filament 410 is clamped in place by support structures (not shown) to keep the wire taught when heated to high temperature, and to provide electrical contact to the wire. A power supply 412a-b is coupled to the filament 410 to provide current to heat the filament 410. A substrate 430 may be positioned under the HWCVD source (e.g., the filaments 410), for example, on a substrate support 428. The power supply 412a-b can be a DC power source. The substrate support 428 may be stationary for static deposition, or may move (as shown by arrow 405) for dynamic deposition as the substrate 430 passes under the HWCVD source. The substrate support 428 may be rotatable.

The chamber body 402 further includes one or more gas inlets (one gas inlet 432 shown) to provide one or more process gases and one or more outlets (two outlets 434 shown) to a vacuum pump to maintain a suitable operating pressure within the processing chamber 400 and to remove excess process gases and/or process byproducts. The gas inlet 432 may feed into the showerhead assembly 433 (as shown), or other suitable gas distribution element, to distribute the gas uniformly, or as targeted, over the filaments 410.

In some implementations, one or more shields 420 may be provided to minimize unwanted deposition on interior surfaces of the chamber body 402. Alternatively or in combination, one or more chamber liners 422 can be used to make cleaning easier. The use of shields, and liners, may preclude or reduce the use of undesirable cleaning gases, such as the greenhouse gas NF3. The shields 420 and chamber liners 422 generally protect the interior surfaces of the chamber body from undesirably collecting deposited materials due to the process gases flowing in the chamber. The shields 420 and chamber liners 422 may be removable, replaceable, and/or cleanable. The shields 420 and chamber liners 422 may be configured to cover every area of the chamber body that could become coated, including but not limited to, around the filaments 410 and on all walls of the coating compartment. Typically, the shields 420 and chamber liners 422 may be fabricated from aluminum (Al) and may have a roughened surface to enhance adhesion of deposited materials (to prevent flaking off of deposited material). The shields 420 and chamber liners 422 may be mounted in the targeted areas of the processing chamber, such as around the HWCVD sources, in any suitable manner. In some implementations, the source, shields, and liners may be removed for maintenance and cleaning by opening an upper portion of the deposition chamber. For example, in some implementations, the lid, or ceiling, of the deposition chamber may be coupled to the body of the deposition chamber along a flange 438 that supports the lid and provides a surface to secure the lid to the body of the deposition chamber.

A controller 406 may be coupled to various components of the processing chamber 400 to control the operation thereof. Although schematically shown coupled to the processing chamber 400, the controller may be operably connected to any component that may be controlled by the controller, such as the power supply 412, a gas supply (not shown) coupled to the gas inlet 432, a vacuum pump and or throttle valve (not shown) coupled to the outlet 434, the substrate support 428, and the like, in order to control the HWCVD deposition process in accordance with the methods disclosed herein. The controller 406 generally comprises a central processing unit (CPU) 408, a memory 413, and support circuits 411 for the CPU 408. The controller 406 may control the HWCVD processing chamber 400 directly, or via other computers or controllers (not shown) associated with particular support system components. The controller 406 may be one of any form of general-purpose computer processor that can be used in an industrial setting for controlling various chambers and sub-processors. The memory 413, or computer-readable medium of the CPU 408 may be one or more of readily available memory such as random access memory (RAM), read only memory (ROM), floppy disk, hard disk, flash, or any other form of digital storage, local or remote. The support circuits 411 are coupled to the CPU 408 for supporting the processor in a conventional manner. These circuits include cache, power supplies, clock circuits, input/output circuitry and subsystems, and the like. The methods as described herein, for example, the method 200, may be stored in the memory 413 as software routine 414 that may be executed or invoked to turn the controller 406 into a specific purpose controller to control the operation of the processing chamber 400 in the manner described herein. The software routine may also be stored and/or executed by a second CPU (not shown) that is remotely located from the hardware being controlled by the CPU 408.

FIG. 5A illustrates a cross-sectional view of a gas distribution plate 500 in accordance with one or more implementations of the present disclosure. FIG. 5B illustrates a perspective cutaway view of the gas distribution plate 500 of FIG. 5A in accordance with one or more implementations of the present disclosure. FIG. 5C illustrates another perspective cutaway view of the gas distribution plate 500 of FIG. 5A in accordance with one or more implementations of the present disclosure.

In one or more implementations, the gas distribution plate 500 is made of a non-conducting ceramic material, for example, graphite. The gas distribution plate 500 may have a coating disposed thereon, for example, a carbide coating. The gas distribution plate includes a ceramic body 502 having a first surface 504, a second surface 506, and a side surface 508. The second surface 506 is opposite the first surface 504 and faces the substrate 430 during use. The ceramic body 502 further includes a plurality of holes 510 extending from the first surface 504 to the second surface 506.

The ceramic body 502 further includes a plurality of radial cavities 512 formed in the second surface 506. The plurality of radial cavities 512 are each sized to accommodate a filament, for example, the filament 410. Referring to FIG. 5C, each radial cavity 512 extends from a center portion of the ceramic body 502 toward the side surface 508 of the ceramic body 502. In one or more implementations, as is shown in FIG. 5C, the second surface 506 includes 48 cavities. Although 48 cavities are depicted in FIG. 5C, any suitable number of cavities may be formed in the second surface 506 of the ceramic body 502. Each of the radial cavities 512 is aligned with a corresponding plurality of holes 510 such that after process gas exits the plurality of holes 510, the process gas flows over the filament 410 positioned within the corresponding cavity 512.

The gas distribution plate 500 further includes one or more electrodes 520a-b. The one or more electrodes 520a-b are positioned to supply power to the one or more filaments 410 positioned in each radial cavity 512. In the implementation depicted in FIG. 5A, a first electrode 520a is positioned adjacent to the side surface 508 of the ceramic body 502 and a second electrode 520b is positioned in a center portion of the ceramic body 502. The one or more electrodes 520a-b can be or include graphite electrodes. The one or more electrodes 520a-b may be electrically coupled with a power source, for example, the power supply 412a-b as shown in FIG. 4

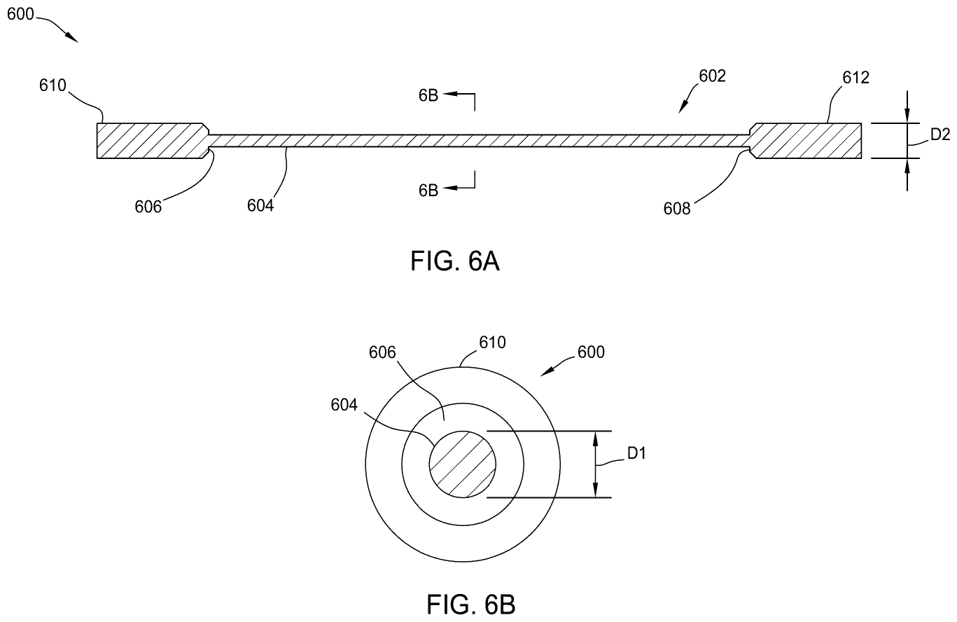

FIG. 6A illustrates a cross-sectional side view of a filament 600 formed in accordance with one or more implementations of the present disclosure. FIG. 6B illustrates a cross-sectional view of the filament 600 of FIG. 6A taken along line 6B-6B in accordance with one or more implementations of the present disclosure. The filament 600 can be used in the gas distribution plate 500. For example, the filament 600 can be used in place of the filament 410a-b. The filament 600 can be formed by the LCVD process as described. The filament 600 can be wholly silicon carbide, wholly tantalum carbide, wholly hafnium carbide filaments, or wholly lanthanum hexaboride as described.

The filament 600 can be a carbide filament or a carbide filament as described herein. The filament 600 can be the filament 600 has a cylindrical body 602. The cylindrical body 602 includes a central portion 604 having a first end 606 and a second end 608. The cylindrical body 602 further includes a first end portion 610 extending from the first end 606 of the central portion 604 and a second end portion 612 extending from the second end 608 of the central portion. The central portion 604 can have a first diameter “D1”. The first diameter “D1” can be a uniform diameter extending along the central portion 604. At least one of the first end portion 610 and the second end portion 612 can have a second diameter “D2”. The second diameter “D2” can be a uniform diameter. In some embodiments, as shown in FIG. 6A, the second diameter “D2” is greater than the first diameter “D1.” The first diameter “D1” can be in a range from about 10 to about 120 micrometers, for example, in a range from about 50 to about 80 micrometers and the second diameter “D2” which is greater than the first diameter “D1” can be in a range from about 10 to about 120 micrometers, for example, in a range from about 50 to about 80 micrometers.

Referring to FIG. 5A, the filament 600 can be positioned in the radial cavity 512 of the gas distribution plate 500 similarly to the filaments 410a-b shown in FIG. 5A. The enlarged diameter “D2” of the first end portion 610 and the second end portion 612 can enable ease of installation in the radial cavity 512.

The previously described implementations of the present disclosure have many advantages, including the following. Metal wire carburization to stabilize resistivity and temperature is avoided by using graphite or carbide coated graphite filaments. That said, ceramic filament improvements are necessary for NCD & UNCD commercialization. The described silicon carbide, tantalum carbide, hafnium carbide and lanthanum hexaboride filaments avoid graphite preforms and thus are more durable than currently available 30 um thick carbide coated 1.63 mm diameter graphite rods and avoid carbon contaminating films. Microwave and arc jet torch diamond deposition is challenging to scale beyond 200 mm wafer diameter. 300 mm NCD and UNCD by catalytic CVD is straightforward but involves production worthy metal-free filaments implemented in assemblies that conform to semiconductor production equipment serviceability requirements. LCVD facilitates three-dimensional high surface area (e.g. helical) filaments that cannot be made by CVD coating graphite. Some implementations provide solid silicon carbide filaments, solid tantalum carbide filaments, solid hafnium carbide filaments, and solid lanthanum hexaboride filaments for NCD and UNCD deposition. The filaments can be used in a constant temperature refractory ceramic diffuser for catalytic CVD of NCD and UNCD films. The NCD and UNCD films can be used as carbon hardmasks. However, the present disclosure does not require that all the advantageous features and all the advantages need to be incorporated into every implementation of the present disclosure.

In the Summary and in the Detailed Description, and the Claims, and in the accompanying drawings, reference is made to particular features (including method operations) of the present disclosure. It is to be understood that the disclosure in this specification includes all possible combinations of such particular features. For example, where a particular feature is disclosed in the context of a particular aspect, implementation, implementation, or example of the present disclosure, or a particular claim, that feature can also be used, to the extent possible in combination with and/or in the context of other particular aspects and implementations of the present disclosure, and in the present disclosure generally.

Implementations and all of the functional operations described in this specification can be implemented in digital electronic circuitry, or in computer software, firmware, or hardware, including the structural means disclosed in this specification and structural equivalents thereof, or in combinations of them. Implementations described herein can be implemented as one or more non-transitory computer program products, i.e., one or more computer programs tangibly embodied in a machine readable storage device, for execution by, or to control the operation of, data processing apparatus, e.g., a programmable processor, a computer, or multiple processors or computers.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them. Processors suitable for the execution of a computer program include, by way of example, both general and special purpose microprocessors, and any one or more processors of any kind of digital computer.

Computer readable media suitable for storing computer program instructions and data include all forms of nonvolatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

The term “comprises” and grammatical equivalents thereof are used herein to mean that other components, ingredients, operations, etc. are optionally present. For example, an article “comprising” (or “which comprises”) components A, B, and C can consist of (i.e., contain only) components A, B, and C, or can contain not only components A, B, and C but also one or more other components. In addition, whenever a composition, an element or a group of elements is preceded with the transitional phrase “comprising” or grammatical equivalents thereof, it is understood that it is contemplated that the same composition or group of elements may be preceded with transitional phrases “consisting essentially of,” “consisting of,” “selected from the group of consisting of,” or “is” preceding the recitation of the composition, element, or elements and vice versa.

Where reference is made herein to a method comprising two or more defined operations, the defined operations can be carried out in any order or simultaneously (except where the context excludes that possibility), and the method can include one or more other operations which are carried out before any of the defined operations, between two of the defined operations, or after all of the defined operations (except where the context excludes that possibility).

When introducing elements of the present disclosure or exemplary aspects or implementation(s) thereof, the articles “a,” “an,” “the” and “said” are intended to mean that there are one or more of the elements.

The terms “comprising,” “including” and “having” are intended to be inclusive and mean that there may be additional elements other than the listed elements.

While the foregoing is directed to implementations of the present disclosure, other and further implementations of the disclosure may be devised without departing from the basic scope thereof, and the scope thereof is determined by the claims that follow.

1. A method of forming a nanocrystalline diamond layer, comprising:
positioning a substrate in a processing region of a processing chamber having a filament disposed therein;
flowing current through the filament to raise a temperature of the filament to a first temperature;
flowing a carbon containing deposition gas over the filament; and
depositing the nanocrystalline diamond layer over the substrate using species decomposed from the carbon containing deposition gas.

2. The method of claim 1, wherein the filament is selected from a carbide containing filament or a boride containing filament.

3. The method of claim 2, wherein the carbide containing filament or the boride containing filament is selected from a silicon carbide (SiC) filament, a tantalum carbide (TaC) filament, a lanthanum hexaboride filament, or a hafnium carbide filament.

4. The method of claim 1, wherein the first temperature is in a range from about 1500 degrees Celsius and about 2500 degrees Celsius.

5. The method of claim 4, wherein the processing region is maintained a pressure of 1 mTorr or greater.

6. The method of claim 1, wherein the processing chamber further comprises:
a gas distribution plate, comprising:
a ceramic body, comprising:
a first surface;
a second surface opposite the first surface;
a side surface extending from the first surface to the second surface;
a plurality of holes extending from the first surface to the second surface; and
a plurality of radial cavities formed in the second surface, wherein each of the radial cavities is aligned with a corresponding plurality of holes; and
the filament positioned in the radial cavities.

7. The method of claim 6, wherein flowing the carbon containing deposition gas over the filament comprises flowing the carbon containing deposition gas through the plurality of holes and over the filament positioned within the corresponding radial cavity.

8. A hot wire chemical vapor deposition (HWCVD) apparatus, comprising:
a chamber body defining an internal processing volume;
a substrate support having a support surface for supporting a substrate;
a gas distribution plate positioned opposite the substrate support, the gas distribution plate, comprising:
a ceramic body, comprising:
a first surface;
a second surface opposite the first surface;
a side surface extending from the first surface to the second surface;
a plurality of holes extending from the first surface to the second surface; and
a plurality of radial cavities formed in the second surface; and
a filament positioned in the radial cavities, wherein the filament is selected from a carbide containing filament or a boride containing filament.

9. The apparatus of claim 8, wherein the carbide containing filament or the boride containing filament is selected from a silicon carbide (SiC) filament, a tantalum carbide (TaC) filament, a lanthanum hexaboride filament, or a hafnium carbide filament.

10. The apparatus of claim 8, further comprising a power source for selectively passing a current through the filament to resistively heat material of the filament.

11. The apparatus of claim 8, wherein each radial cavity extends from a center portion of the ceramic body toward the side surface of the ceramic body.

12. The apparatus of claim 8, wherein each of the radial cavities is aligned with a corresponding plurality of holes such that after process gas exits the plurality of holes the process gas flows over the filament positioned within the corresponding radial cavity.

13. The apparatus of claim 8, wherein the filament comprises:
a cylindrical body, comprising:
a central portion having a first end and a second end;
a first end portion extending from the first end of the central portion; and
a second end portion extending from the second end of the central portion, wherein the central portion has a first diameter and at least one of the first end portion and the second end portion has a second diameter, and the second diameter is greater than the first diameter.

14. The apparatus of claim 8, further comprising:
a controller configured to execute instructions stored on a computer readable medium for a method of forming a nanocrystalline diamond layer, the method comprising:
flowing current through the filament to raise a temperature of the filament to a first temperature;
flowing a carbon containing deposition gas over the filament; and
depositing a nanocrystalline diamond layer over the substrate using species decomposed from the carbon containing deposition gas.

15. A gas distribution plate, comprising:
a ceramic body, comprising:
a first surface;
a second surface opposite the first surface;
a side surface extending from the first surface to the second surface;
a plurality of holes extending from the first surface to the second surface; and
a plurality of radial cavities formed in the second surface; and
a filament positioned in the radial cavities, wherein the filament is selected from a carbide containing filament or a boride containing filament.

16. The gas distribution plate of claim 15, wherein the carbide containing filament or the boride containing filament is selected from a silicon carbide (SiC) filament, a tantalum carbide (TaC) filament, a lanthanum hexaboride filament, or a hafnium carbide filament.

17. The gas distribution plate of claim 15, wherein each radial cavity extends from a center portion of the ceramic body toward the side surface of the ceramic body.

18. The gas distribution plate of claim 15, wherein each of the radial cavities is aligned with a corresponding plurality of holes such that after process gas exits the plurality of holes the process gas flows over the filament positioned within the corresponding radial cavity.

19. The gas distribution plate of claim 15, wherein the filament comprises:
a cylindrical body, comprising:
a central portion having a first end and a second end;
a first end portion extending from the first end of the central portion; and
a second end portion extending from the second end of the central portion, wherein the central portion has a first diameter and at least one of the first end portion and the second end portion has a second diameter, and the second diameter is greater than the first diameter.

20. The gas distribution plate of claim 15, wherein the ceramic body comprises graphite and the ceramic body has a carbide coating disposed thereon.
